(19) United States
(12) Patent Application Publication
(10) Pub. No.: US 2012/0025039 A1
(43) Pub. Date: Feb. 2, 2012

(54) Cell Phone Holder and Stand

(76) Inventor: Stanley H. Segal, Boca Raton, FL (US)

(21) Appl. No.: 13/192,772

(22) Filed: Jul. 28, 2011

Related U.S. Application Data
(60) Provisional application No. 61/368,454, filed on Jul. 28, 2010.

(51) Int. Cl. H05K 7/00

(52) U.S. Cl. 248/188.6

(57) ABSTRACT

An article for holding and standing a cell phone having a main body; an arm extending upward from said main body; a holder incorporated on an upper terminal end of said arm; a standing leg; and a pivot pin constructed and arranged such that the standing leg is moved from a position substantially coplanar with said main body to a position outward from said main body.

### INDEX TO RELATED APPLICATIONS

This application claims the benefit of U.S. Provisional Patent Application No. 61/368,454 filed Jul. 28, 2011 the disclosure of which is incorporated herein by reference in its entirety.

### FIELD OF INVENTION

The subject invention relates to a multi use cell phone holder and stand.

### BACKGROUND OF THE INVENTION

The cellular telephone is an ever present fixture in our world today. Along with advances in cellular technology, there are advances in articles to be utilized with cellular telephones. Cell phone holders come in many sizes, shapes and configurations. A significant limitation in cell phone holders and cases is that they must me sized and shaped for every size and shape of cell phone. This task is difficult and presents a problem relating to manufacturing.

The current invention not only addresses this problem, but the present invention is configured to be utilized with a vast variety of cell phones in a single configuration.

### SUMMARY OF THE INVENTION

In one embodiment the present invention is an article for holding and standing a cell phone having:
a. a main body;
b. an arm extending upward from said main body;
c. a holder incorporated on an upper terminal end of said arm;
d. a standing leg extending attached to said main body;
e. a pivot pin constructed and arranged such that said leg is moved from a position substantially coplanar with said main body to a position out word from said main body.

The article main body is attached directly to a cell phone, a user supplied cell phone case/holder, or a user supplied cell phone skin.

The article has a holder that is integral with a retractable arm and formed of a single contiguous piece. In one embodiment, the holder is a retractable ring assembly formed integral along two leg portions that slide outward from the main body and are retractable to within the main body.

In one embodiment, leg extending downward from said main body is constructed and arranged to pivot from angles between 0-90° relative to the plane in which said main body lies.

The standing leg moves away from the main body and is used to stand the article in either a horizontal or vertical position.

The holder in one embodiment is a ring assembly.

The arm is constructed and arranged to slidably extend and retract along a coplaner orientation with said main body.

The arm is constructed and arranged to slidably extend and retract along a coplaner orientation with said main body and wherein said arm is constructed to prevent complete separation from said main body.

In one embodiment, the holder is configured to be held by at least one human finger.

The holder is also configured to be hung on a hanger.

Hanger would mean any article capable of engaging the hanger or ring and hanging the article thereon.

The present invention further contemplates A kit having:
the article as described herein; and
a hanging device for hanging said article thereon.

The hanging device, in one embodiment, is supplied in the kit of the invention as a hanging hook with mounting adhesive incorporated thereon.

Additional aspects, advantages and novel features of the invention will be set forth in part in the description which follows, and in part will become apparent to those skilled in the art upon examination of the following or may be learned by practice of the invention. The aspects and advantages of the invention may be realized and attained by means of the instrumentalities and combinations particularly pointed out in the appended claims.

### BRIEF DESCRIPTION OF THE SEVERAL VIEWS OF THE DRAWINGS

FIG. 1 is a perspective view of the invention in an environment of use.

FIG. 2 is a perspective view of the invention with leg assembly extended.

FIG. 3 is a perspective view of the invention in a horizontal orientation with leg assembly extended.

FIG. 4 is a front view of the invention in an environment of use showing placement of a finger through a ring and ring cavity.

FIG. 5 is a perspective View showing the assembly hanging on a hanger.

FIG. 6 is a front view showing the ring assembly fully extended.

FIG. 7 is a back view showing the assembly of an invention showing the assembly of the invention with an adhesive attaching area.

### DESCRIPTION OF THE PREFERRED EMBODIMENTS

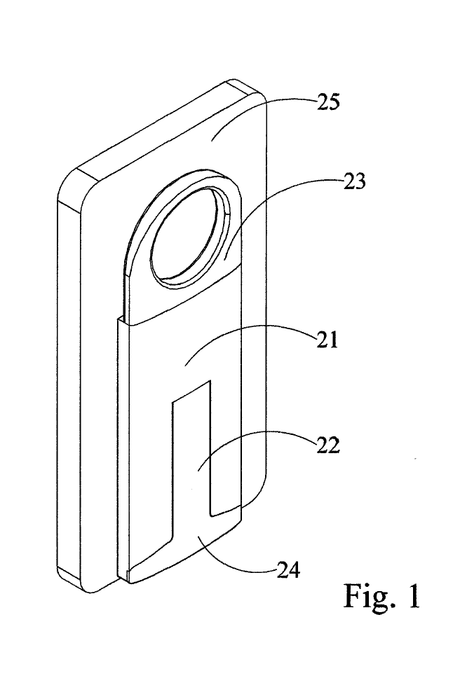

As seen in FIG. 1, the present invention is an article whereby assembly 10 comprises a main body 21 that attaches to a cell phone case 25 or in the alternative the actual backing of a cell phone (not shown). Standing leg 22 terminates in a leg end 24. Ring assembly 23 is extendable outward from main body 21.

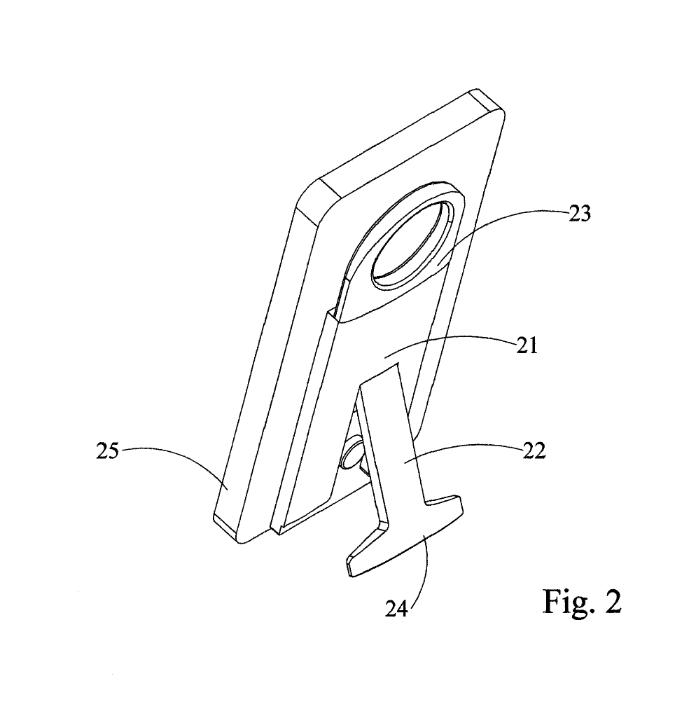

As seen in FIG. 2, standing leg assembly 22 is pivotably extended from main body 21 and includes a leg end 24 for use as a stand.

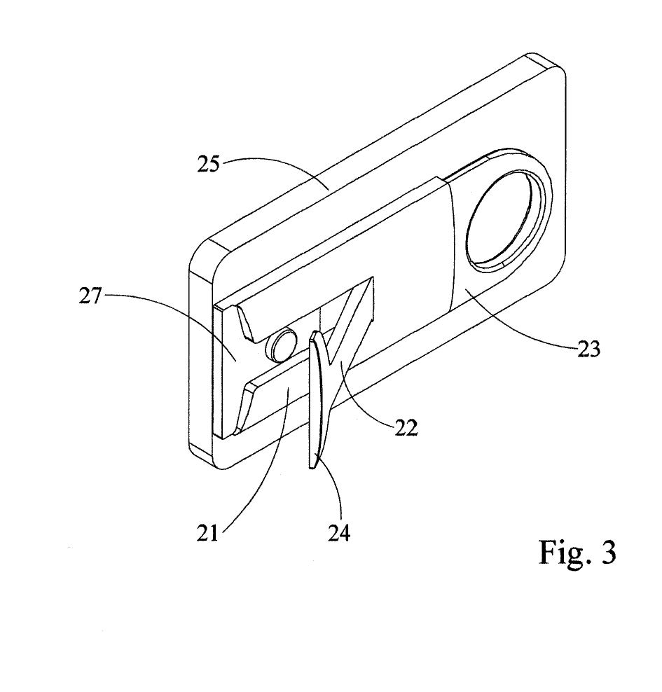

As seen in FIG. 3, main body 21 can be oriented in a horizontal position such that when standing leg 22 is extended, leg end 24 will also support the cell phone in a standing position.

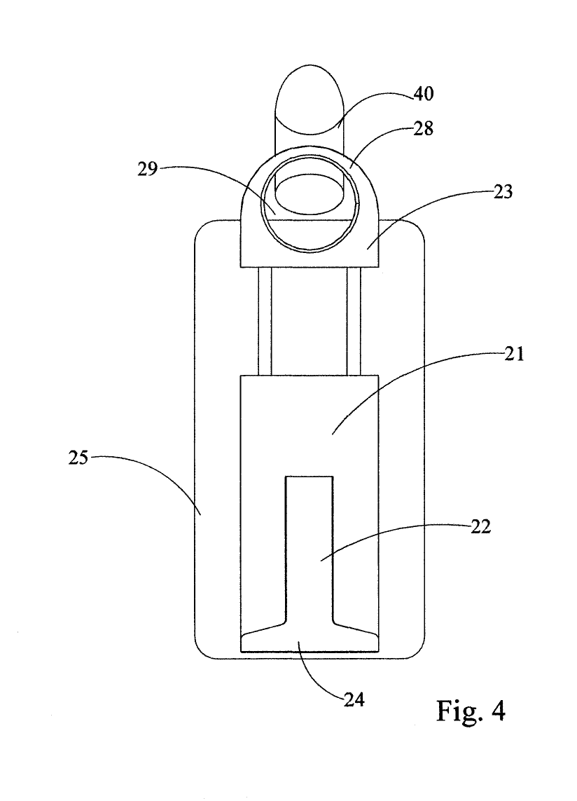

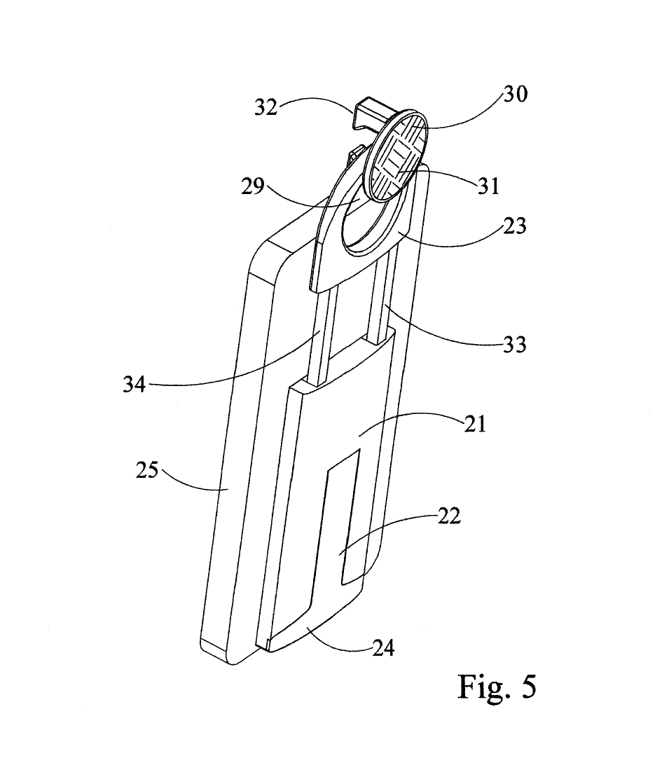

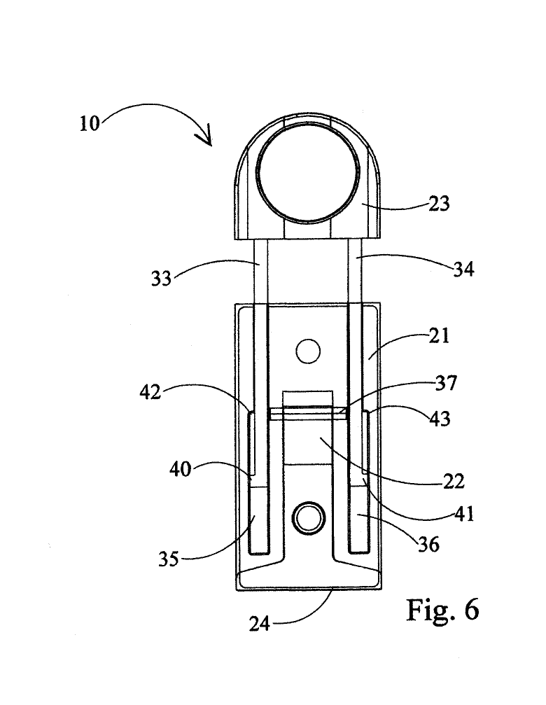

As seen in FIG. 4, ring assembly 23 is extendable upward from main body 21 such that ring 28 defines a ring cavity 29 and is constructed and arranged for a person's finger 40 to pass through ring cavity 29. In this orientation, a person can hold the assembly by passing their finger 40 through ring cavity 29. As seen in FIG. 5, a hanger 30 is utilized with the assembly. Hanger 30 has incorporated thereon adhesive 31, which allows for adhesive mounting to a flat surface. In one embodiment, the adhesive mounting 31 may be affixed to an automobile dashboard such that the assembly may be hung in an automobile. Incorporated with hanger 30 are one or more hanger arms 32 constructed and arranged such that ring 28 interacts therewith and allows for hanging of the cell phone assembly 10. Ring assembly 23 is extendable and retractable from main body 21 by means of a first arm 33 and a second arm 34 attached to ring assembly 23. Each of first arm 33 and second arm 34 are constructed and arranged such that they extend outward from main body 21 and have internal structure to prevent complete disassembly from main body 21. As seen in FIG. 6 which is a cutaway of main body 21 showing each of first arm 33 and second arm 34 that extend outward from main body 21 and corresponding first track 35 and second track 36 therein which facilitates the extension and retraction of ring assembly 23 from main body 21.

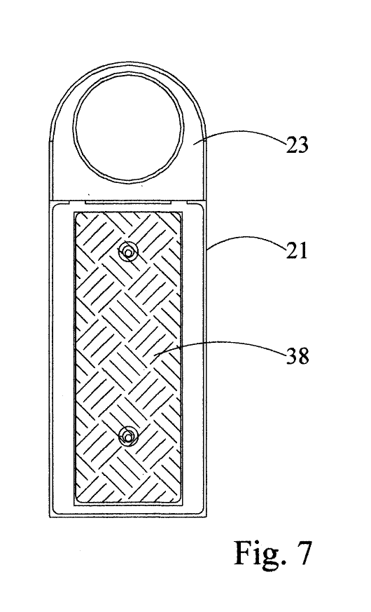

In the embodiment shown in FIG. 7, main body 21 has an adhesive surface 38 incorporated thereon. Adhesive surface 38 can be attached to a conventional cell phone cover 25 or in the alternative maybe attached directly to a cell phone casing. In one embodiment demonstrating use, the article is used by attaching assembly 10 to a cell phone. By attaching, it is understood that the article is attached directly to a cell phone housing, or, in alternative, to an existing cell phone cover 25 or skin (not shown). The present invention offers a distinct advantage in that it need not be offered in multiple configurations to accommodate different cell phone sizes and shapes. A single configuration attaches either to the actual cell phone housing or to a cover 25 or skin whereby the cover or skin is the article sized and shaped for a particular cell phone. Main body 21 has adhesive 38 disposed thereon. Adhesive 38 is attached directly to a cover 25, cell phone skin, or directly to a cell phone housing.

The present invention is constructed and arranged to function as a stand and to stand a phone in a vertical position, as in FIG. 2, or a horizontal position, as in FIG. 3.

Standing is accomplished by pivotably moving standing leg 22 outward from main body 21. Standing leg 22 has end 24 that is elongated and the elongated configuration allows for stablization of article 10 when used as a stand.

Ring assembly 23 slidably extends out from a retracted position in which most of each of first leg 33 and second leg 34 are contained within the inner portion of main body 21. First arm 33 and second arm 34 extend outward from main body 21 and slide along corresponding first track 35 and second track 36 constructed on the interior of main body 21. The sliding facilitates the extension and retraction of ring assembly 23 from main body 21. First leg 33 and second leg 34 each have a flanged terminal end 40 and 41 respectively wherein each flanged terminal end 40 and 41 is integral with respective first leg 33 and second leg 34 and opposite ring assembly 23. Each flanged terminal end 40 and 41 inhibits first leg 33 and second leg 34 from being retracted completely outside of main body 23 by configuration of a first curved edge 42 and a second curved edge 43 along the uppermost edge of each of first track 35 and second track 36. When ring assembly 23 is extended outward from main body 21, the first flanged end 40 and second flanged end 41 will contact first curved edge 42 and a second curved edge 43 along the uppermost edge of each of first track 35 and second track 36 and inhibit ring assembly 23 from being completely separated from main body 21.

Once ring assembly 23 is retracted, ring cavity 29 defined by ring 28 is accessed as needed.

One embodiment of access is for a user to insert a finger 40 through ring cavity 29 and hold assembly 10 on finger 40.

Another embodiment allows assembly 10 to be hung utilizing any suitable hanging device. In one embodiment, a hanging hook 30 is provided with article 10 and hanging hook 30 is adhesively attached utilizing adhesive 31 disposed thereon.

While the invention has been described in its preferred form or embodiment with some degree of particularity, it is understood that this description has been given only by way of example and that numerous changes in the details of construction, fabrication, and use, including the combination and arrangement of parts, may be made without departing from the spirit and scope of the invention.

I claim:

1. An article for holding and standing a cell phone and a method for using said article comprising:
a. a main body;
b. an arm extending upward from said main body;
c. a holder incorporated on an upper terminal end of said arm;
d. a pivotable standing leg attached to said main body;
e. a pivot pin constructed and arranged such that said standing leg is pivotably moved from a position substantially coplanar with said main body to a position out word from said main body.

2. The article of claim 1 wherein said main body is attached directly to a cell phone.

3. The article of claim 1 wherein said main body is incorporated in or on a cell phone holder or cell phone skin.

4. The article of claim 1 wherein said holder is integral with said arm and formed of a single contiguous piece.

5. The article of claim 1 wherein said standing leg is constructed and arranged to pivot away from said main body from angles between 0-90° relative to the plane in which said main body lies.

6. The article of claim 1 wherein holder is a ring assembly.

7. The article of claim 1 wherein said arm is constructed and arranged to slidably extend and retract along a coplaner orientation with said main body.

8. The wherein said arm is constructed and arranged to slidably extend and retract along a coplaner orientation with said main body and wherein said arm is constructed to prevent complete separation from said main body.

9. The article of claim 1 wherein holder is configured to be held by at least one human finger.

10. The article of claim 1 wherein holder is configured to be hung on a hanger.

11. A kit comprising:
the article of claim 1; and
a hanging device for hanging said article thereon.
